(19) United States
(12) Patent Application Publication
(10) Pub. No.: US 2006/0138630 A1
(43) Pub. Date: Jun. 29, 2006

(54) Stacked ball grid array packages

(75) Inventor: Jayesh R. Bhakta, Cerritos, CA (US)

Correspondence Address: KLEIN, O'NEILL & SINGH, 2 PARK PLAZA, SUITE 510, IRVINE, CA, 92614, US

(73) Assignee: NETLIST, INC., Irvine, CA (US)

(21) Appl. No.: 11/314,968

(22) Filed: Dec. 21, 2005

Related U.S. Application Data
(60) Provisional application No. 60/639,864, filed on Dec. 28, 2004.

(51) Int. Cl. H01L 23/02

(52) U.S. Cl. 257/686

(57) ABSTRACT

An arrangement of ball grid array packages includes a flexible circuit board having first and second opposed surfaces defining a central portion to which first and second side portions are flexibly attached. A first package has a first array of solder ball pins attached to the first surface of the circuit board in the central portion thereof. A second package has first and second opposed surfaces and a second array of solder ball pins on the first surface that are attached to the second surface of the circuit board in the central portion thereof. A third array of solder ball pins is provided on each of the side portions on the first surface thereof. The side portions are folded underneath the second package and attached to the second surface thereof, whereby the third array of solder ball pins is oriented for attachment to a motherboard.

### CROSS-REFERENCE TO RELATED APPLICATIONS

This application claims the benefit, under 35 U.S.C. §119(e), of co-pending provisional application No. 60/639,864; filed Dec. 28, 2004, the disclosure of which is incorporated herein by reference.

### FEDERALLY-SPONSORED RESEARCH OR DEVELOPMENT

Not Applicable

### BACKGROUND OF THE INVENTION

This invention relates generally to the field of packaging and installing electronic components and circuits in a device employing such components and circuits. More specifically, it relates to a novel arrangement of electronic components and circuits, of the type packaged in so-called “ball grid array” (“BGA”) packages, that facilitates space-efficient installation in an electronic device.

Many miniature, solid state electronic components, such as memory chips, are packaged in what is termed a “ball grid array” package, or “BGA” package. A typical BGA package includes an encapsulated component having conductive leads that extend to a major planar surface of the package. The leads extend to the exterior of the package and terminate in an array of solder ball terminations. The solder ball terminations function as conductive pins, and thus are located so as to establish electrical contact with corresponding terminal pads on a circuit board.

In many compact electronic devices, such as portable computers, space for circuit boards is severely limited. To decrease the space occupied by such board-mounted components as memory chips, it is necessary to increase the density of the circuit boards by means such as package stacking. Typically, stacking involves the vertical stacking of two or more board-mounted components, in die or packaged form, one on top of the other, with like pins or leads connected. While some types of packages, such as, for example, Thin Small Outline Packages (TSOPs), are relatively easy to configure in a vertically stacked arrangement, packages with small form factors, such as BGA packages, are more difficult and require more complex arrangements to provide the appropriate pin connections.

One arrangement for stacking BGA packages involves the use of flexible circuit boards, or “flex circuits.” Flex circuits can be folded, so that the pins of adjacently-stacked components can be more easily connected. Other arrangements employ rigid circuit boards. Whether a rigid board or a flex circuit is used, in the prior art the packages are stacked “front-to-back” (or top-to-bottom), so that each pin of one component is vertically aligned with the corresponding connecting pin of the next adjacent component (i.e., pins 1, 2, 3 . . . n of the first component are respectively aligned with, and connected to, pins 1, 2, 3 . . . n of the next adjacent component). This arrangement requires asymmetric trace lengths to the pins, resulting in signals reaching the lower components in the stack before they reach the upper components. Such asymmetry in signal path lengths, while acceptable at relatively low signal frequencies, can cause functionality problems at higher frequencies due to signal reflections and signal transmission time disparities. Furthermore, the relatively dense stacking of components in a top-to-bottom relationship can result in unequal heat dissipation. Specifically, the lower components, that are closer to the circuit board, can conduct heat much more efficiently than the upper components. The higher operating temperatures of the upper components causes them to operate, generally, at slower speeds, causing disparities in the response times of the individual components in each stack, which can lead to serious functionality problems at higher operational speeds. The asymmetric signal path lengths inherent in front-to-back stacking assemblies further exacerbate these problems.

Thus, with the increase in operational speeds of components such as memory chips, there has been an increasing need for solutions to the problems resulting from asymmetric signal paths and unequal heat dissipation in stacked components.

### SUMMARY OF THE INVENTION

Broadly, the present invention is a stacked arrangement of ball grid array (BGA) packages, in which at least first and second BGA packages are stacked “back-to-back” (or bottom-to-bottom), using a flexible circuit board or “flex circuit” having a central portion that underlies the first package and opposing side portions that are folded down and under the second package. In this stacked arrangement, the first package is an upper component and the second package is a lower component. The central portion of the flex circuit has a first array of contact pads on its upper surface that correspond to the ball grid terminations or pins of the upper component, and a second array of contact pads on its lower surface that correspond to the ball grid terminations or pins of the lower component. Each of the side portions of the flex circuit has an array of ball grid terminations or pins on its top surface that, when folded down and under the lower component, form a ball grid array of pins for connecting the lower component (and thus the entire stacked array) to another PC board, such as a main or “motherboard.”

In manufacturing the stacked arrangement of the invention, a flex circuit, as described above, is provided. A first or upper BGA package or component is installed on the upper surface of the central portion of the flex circuit, so that each of the pins of the upper BGA package or component is connected to a corresponding contact pad in the first array of contact pads. A second or lower BGA package or component is installed on the lower surface of the central portion of the flex circuit, so that each of the pins of the lower BGA package or component is connected to a corresponding contact pad in the second array of contact pads. The side portions of the flex circuit are then folded or bent down and toward each other under the lower BGA component, and adhesively attached to the lower (front) surface of that component. When so folded against and attached to the lower or front surface of the lower BGA component, the ball grid terminations or pins of the two side portions of the flex circuit underlie the lower component and thus are exposed to provide the means for connecting the lower component, and thus the entire stacked arrangement, to a main circuit board or “motherboard.”

With the arrangement described above, asymmetries in length among the several conductive signal traces connecting the pins of the upper and lower components are minimized. To minimize further such asymmetries, one or more conductive vias may advantageously be provided through the flex circuit to provide direct “inter-layer” conductive paths for connecting an upper BGA pin to a lower BGA pin.

As will be more fully appreciated from the detailed description that follows, the present invention provides a stacked BGA arrangement in which signal path lengths are made more symmetrical than has heretofore been feasible in the prior art, without sacrificing component density, and without increasing costs. The result is a product that minimizes signal reflections and signal transmission time disparities, thereby facilitating high speed (high frequency) operation. Furthermore, the “back-to-back” arrangement of the upper and lower components produces allows for better heat dissipation from the upper component, thereby further contributing to more reliable high speed operation.

### BRIEF DESCRIPTION OF THE DRAWINGS

FIG. 1 is an idealized cross-sectional view of a stacked arrangement of ball grid array (BGA) packages, in accordance with a preferred embodiment of the present invention;

FIG. 2A is a top plan view of a strip of flex circuits of the type used in the present invention;

FIG. 2B is a bottom plan view of the flex circuit strip of FIG. 2A;

FIG. 2C is a vertical cross-sectional view of the flex circuit shown in FIGS. 2A and 2B;

FIG. 3 is a side elevational view of the flex circuit strip of FIGS. 2A and 2B;

FIG. 4 is a perspective view of a stacked arrangement of BGA packages, prior to the folding of the side portions of the flex circuit;

FIG. 5 is a plan view of a flex circuit, of the type used in the present invention; and

FIG. 6 is a diagrammatic representation of the connections between a PC Board and a stacked arrangement of BGA packages according to the present invention.

### DETAILED DESCRIPTION OF THE INVENTION

Referring first to FIGS. I and 4, a stacked arrangement or assembly 10 of ball grid array (BGA) packages or components comprises a first or upper BGA component 12a and a second or lower BGA component 12b, both of which are connected to a flex circuit 14 in a manner to be described below. The upper BGA component 12a includes a first array of solder ball terminals or pins 16a on its back or bottom surface, while the lower BGA component includes a second array of solder ball terminals or pins 16b on its back or bottom surface. As described in more detail below, the upper BGA component 12a and the lower BGA component 12b are mounted on the upper and lower surfaces, respectively, of the flex circuit 14, so that the two BGA components 12a, 12b are effectively mounted back-to-back (or bottom-to-bottom).

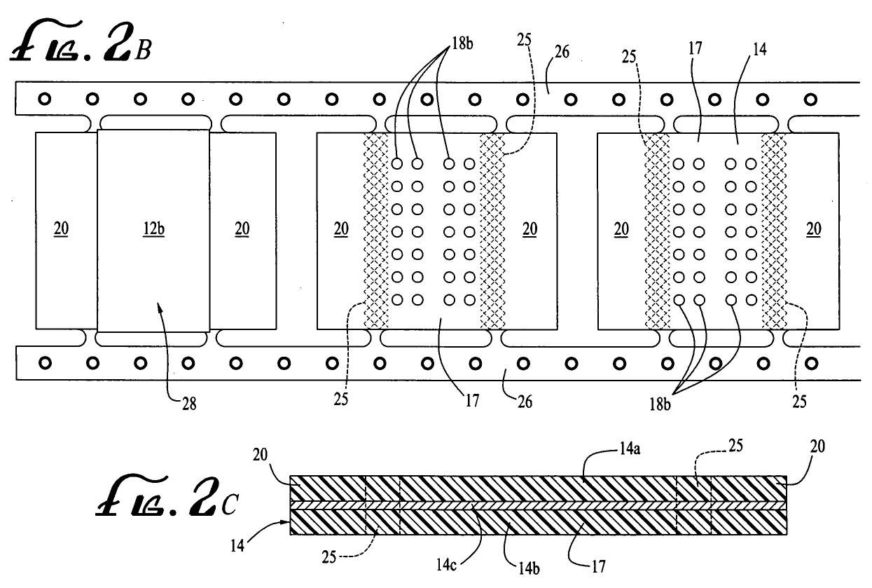

As best shown FIGS. 2A, 2b, and 2C, the flex circuit 14 is a flexible circuit board of approximately 5 mil (0.012 mm) total thickness. The flex circuit 14 preferably comprises a laminate of two or more insulative layers, preferably of a suitable polymer, such as, for example, a polyamide. In a preferred exemplary embodiment, the flex circuit 14 comprises an upper polyamide layer 14a laminated to a lower polyamide layer 14b. The lower polyamide layer 14b is metal-plated to form an internal metal layer 14c, to be described in greater detail below. The flex circuit 14 has a central portion 17 with a first array of contact pads 18a on its upper surface and a second array of contact pads 18b on its lower surface. Each of the first array of contact pads 18a corresponds to one of the pins 16a of the upper BGA component 12a, and each of the second array of contact pads 18b corresponds to one of the pins 16b of the lower BGA component 12b. Thus, each of the pins 16a of the upper component 12a is connected to a corresponding one of the pads 18a in the first pad array on the upper surface of the flex circuit 14, while each of the pins 16b of the lower component 12b is connected to a corresponding one of the pads 18b in the second pad array on the lower surface of the flex circuit 14.

The flex circuit 14 also includes a pair of opposed side portions 20, each of which has, on its upper surface, an array of solder ball terminals or pins 22. Each of the side portions further includes an adhesive layer 24 on its lower surface. Each of the side portions 20 is joined to the central portion 17 by a highly-flexible transition portion 25 that can be bent or folded relatively sharply, as discussed below, without suffering any structural damage, such as cracking. To facilitate such bending, the internal metal layer 14c in each of the transition portions 25 is formed as a latticework (shown in phantom in FIGS. 2A and 2B) that is created by masking and photo-etching the metal layer 14c before the polyamide layers 14a, 14b are laminated together to form the laminated flex circuit 14.

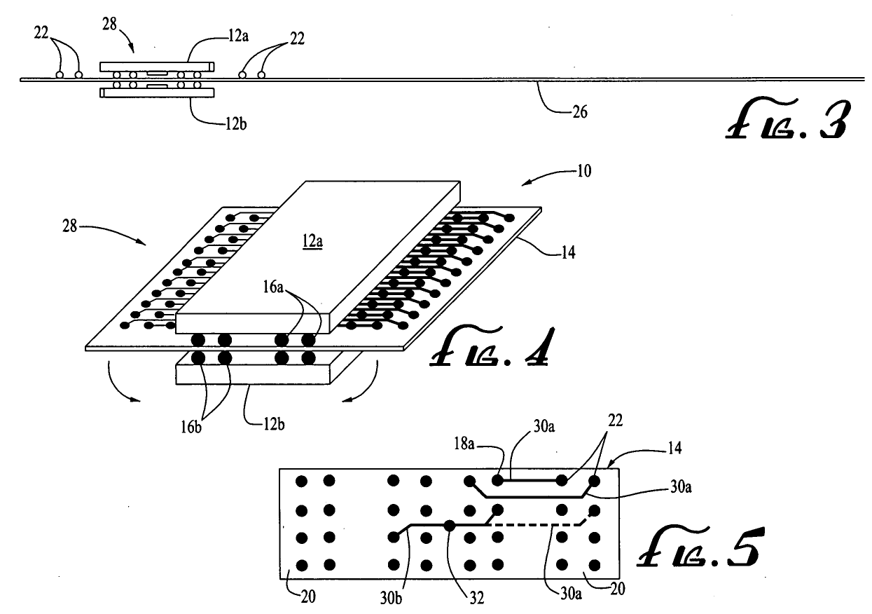

In FIGS. 2A, 2B, and 3, a strip comprising a plurality of flex circuits 14 is shown, with the flex circuits 14 being attached to a pair of opposed carrier bands 26, in accordance with conventional manufacturing processes. On the left side of each of these drawing figures, a partially-finished assembly 28 is shown, comprising a flex circuit 14 with an upper component 12a and a lower component 12b attached to it by means of the solder ball pins 16a, 16b of the upper and lower components, respectively, being soldered to the respective contact pads 18a, 18b, as described above.

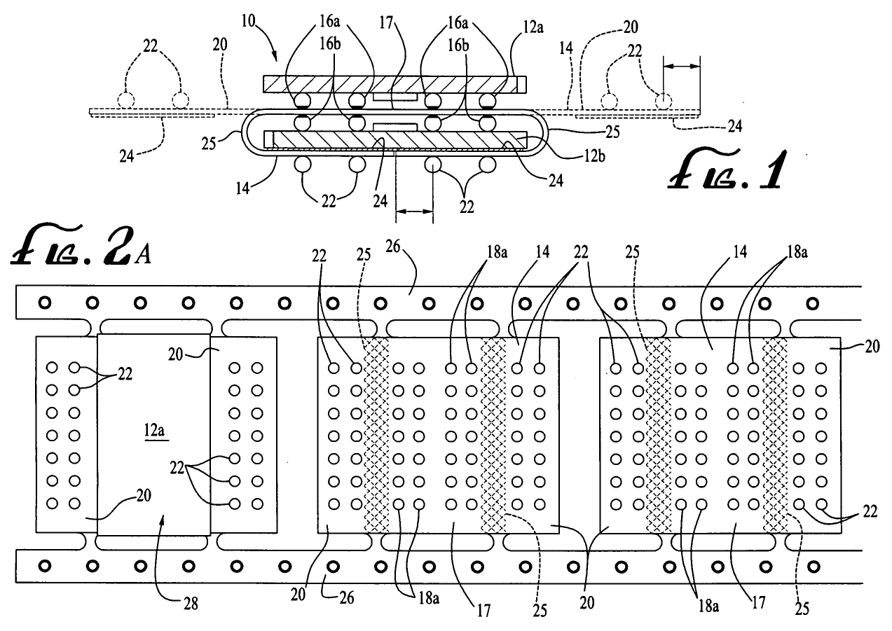

After the attachment of the components 12a, 12b, the side portions 20 of each of the flex circuits 14 are folded or bent down and toward each other, at the transition portions 25, underneath and against the lower or front surface of each of the lower components 12b. The side portions 20 are adhesively attached to the exposed lower surface of the lower component 12b by means of the adhesive layers 24 mentioned above. This folding or bending step is best shown in FIG. 1, in which the side portions 20 are shown in phantom prior to the folding or bending step, and in solid outline after attachment to the lower or front surface of the lower component 12b. As shown in FIG. 1, this folding or bending places the solder ball pins 22 of the flex circuit side portions 20 directly underneath the lower or front surface of the lower component 12b, so that they may be used to attach the stacked arrangement to a PC board (e.g., a “motherboard”). The folding or bending step may be performed either before the partially-finished assembly 28 is separated from the carrier bands 26, or after its separation therefrom.

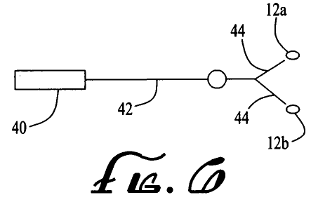

FIG. 4 illustrates a partially-finished assembly 28 that has been separated from the carrier bands 26 before the step of folding or bending the side portions 20 of the flex circuit against the front or bottom surface of the lower component 12b. FIG. 5 illustrates a simplified flex circuit 14, of the type employed in the present invention. Both of these figures show a plurality of conductive traces that are formed on the flex circuit 14, by conventional means (such as screen printing or photo etching), to connect the contact pads 18a, 18b in the central portion of the flex circuit 14 with each other and with their respective pins 22 of the flex circuit side portions 20. As best shown in FIG. 5, each of a first plurality of traces 30a connects an upper or lower contact pad 18a, 18b with a corresponding side portion solder ball pin 22, while each of a second plurality of traces 30b connects a lower contact pad 18b with a corresponding upper contact pad 18a. Appropriate connections between selected ones of the first and second plurality of traces may advantageously be made, where desired, by means of one or more conductive vias 32 provided through the flex circuit 14, as shown in FIG. 5, whereby selected upper component pins 16a may be connected to their respective lower component pins 16b. The result is an array of traces in which asymmetries among trace lengths are minimized.

As shown in FIG. 6, the finished stack assembly 10 may be used to build memory modules by assembling a number of such stacked assemblies on a printed circuit (PC) board. The stacked assembly 10 receives electrical signals via contacts 40 at the connector edge of the memory module (only a single such contact 40 being shown in FIG. 6). These signals go to the appropriate solder ball pins 16a, 16b of the BGA components 12a, 12b, respectively, of each stacked assembly, through metallized conductive vias built inside the flex circuit (as shown, for example in FIG. 5), or conductive traces 42, 44 etched on the surface of the flex circuit. In either case, the lengths of the signal paths are shortened and symmetry is achieved.

While an exemplary embodiment of the invention has been described herein, it will be appreciated that a number of variations and modifications will suggest themselves to those skilled in the pertinent arts. It is understood that such variations and modifications may be deemed within the expected range of equivalents to the specific embodiment disclosed herein, and thus within the scope of the invention as defined by the claims appended hereto.

What is claimed is:

1. A stacked arrangement of ball grid array (BGA) packages, the arrangement comprising:
a flexible circuit board having first and second opposed surfaces, a central portion, and a side portion extending from each of two opposed sides of the central portion;
a first array of contact pads on the first surface of the flexible circuit board and in the central portion thereof;
a second array of contact pads on the second surface of the flexible circuit board and in the central portion thereof;
a lower array of contact pads on the first surface of the flexible circuit board in each of the side portions thereof;
a first BGA package having an upper array of solder ball pins on a first surface thereof, each pin in the upper array of pins being fixed to a corresponding one of the contact pads in the first array of contact pads; and
a second BGA package having first and second opposed surfaces and a middle array of solder ball pins on the first surface thereof, each pin in the middle array of pins being fixed to a corresponding one of the contact pads in the second array of contact pads;
wherein side portions of the flexible circuit board are folded around the second BGA package so as to be fixed, at the second surface thereof, to the second surface of the second BGA package, whereby the lower array of contact pads is exposed for attachment to a mother board.

2. The arrangement of claim 1, wherein the flexible circuit board comprises a metal-plated lower polymer layer laminated to an upper polymer layer.

3. The arrangement of claim 2, wherein the polymer includes a polyamide.

4. The arrangement of claim 1, wherein each of the side portions of the flexible circuit board is joined to the central portion by a highly flexible transition portion.

5. The arrangement of claim 4, wherein the flexible circuit board includes an internal metal layer, wherein the metal layer is formed as a latticework in the transition portions.

6. A flexible circuit board for mounting first and second ball grid array (BGA) packages on a motherboard, comprising:
a first array of contact pads on a central portion of a first surface;
a second array of contact pads on a central portion of a second surface opposed to the first surface; and
an array of solder ball pins on each of two side portions of the first surface, the side portions extending from opposite sides of the central portion;
wherein the side portions are foldable relative to the central portion so as to bring the solder ball pins on the side portions directly underneath the central portion of the second surface so as to be attachable to the motherboard.

7. The flexible circuit board of claim 6, wherein the flexible circuit board comprises a metal-plated lower polymer layer laminated to an upper polymer layer.

8. The flexible circuit board of claim 7, wherein the polymer includes a polyamide.

9. The flexible circuit board of claim 6, wherein each of the side portions of the flexible circuit board is joined to the central portion by a highly flexible transition portion.

10. The flexible circuit board of claim 9, wherein the flexible circuit board includes an internal metal layer, wherein the metal layer is formed as a latticework in the transition portions.

11. An arrangement of ball grid array (BGA) packages, comprising:
a flexible circuit board having first and second opposed surfaces defining a central portion and first and second side portions extending from opposite sides of the central portion;
a first BGA package having a first array of solder ball pins on a first surface thereof that are conductively attached to the first surface of the flexible circuit board in the central portion thereof;
a second BGA package having first and second opposed surfaces and a second array of solder ball pins on the first surface thereof that are conductively attached to the second surface of the flexible circuit board in the central portion thereof; and
a third array of solder ball pins on each of the side portions of the flexible circuit board on the first surface thereof;
wherein the second surface of the flexible circuit board is attached at the side portions thereof to the second surface of the second BGA package, so as to orient the third array of solder ball pins for attachment to a motherboard.

12. The arrangement of claim 11, wherein the first array of solder ball pins is attached to a first array of contact pads on the first surface of the flexible circuit board, and the second array of solder ball pins is attached to a second array of contact pads on the second surface of the flexible circuit board.

13. The arrangement of claim 11, wherein the flexible circuit board comprises a metal-plated lower polymer layer laminated to an upper polymer layer.

14. The arrangement of claim 13, wherein the polymer includes a polyamide.

15. The arrangement of claim 11, wherein each of the side portions of the flexible circuit board is joined to the central portion by a highly flexible transition portion.

16. The arrangement of claim 15, wherein the flexible circuit board includes an internal metal layer, wherein the metal layer is formed as a latticework in the transition portions.
